(19) United States
(12) Patent Application Publication
(10) Pub. No.: US 2017/0271850 A1
(43) Pub. Date: Sep. 21, 2017

(54) Nanolasers for Solid-State Lighting

(71) Applicant: Sandia Corporation, Albuquerque, NM (US)

(72) Inventor: Weng W. Chow, Cedar Crest, NM (US)

(21) Appl. No.: 15/458,362

(22) Filed: Mar. 14, 2017

Related U.S. Application Data
(60) Provisional application No. 62/311,128, filed on Mar. 21, 2016.

(51) Int. Cl. H01S 5/40; H01S 5/10; H01S 5/125; H01S 5/323

(52) U.S. Cl. CPC H01S 5/4093; H01S 5/32341; H01S 5/1042; H01S 5/125

(57) ABSTRACT

Nanolaser arrays have certain advantages over LEDs and conventional laser diodes for solid-state lighting applications. In particular, nanocavities can channel spontaneous emission entirely into the lasing mode, so that all the emissions (spontaneous and stimulated) contribute to usable light output over a large range of current.

### CROSS-REFERENCE TO RELATED APPLICATION

This application claims the benefit of U.S. Provisional Application No. 62/311,128, filed Mar. 21, 2016, which is incorporated herein by reference.

### STATEMENT OF GOVERNMENT INTEREST

This invention was made with Government support under contract no. DE-AC04-94AL85000 awarded by the U. S. Department of Energy to Sandia Corporation. The Government has certain rights in the invention.

### FIELD OF THE INVENTION

The present invention relates to solid-state lighting and, in particular, to the use of nanolasers for solid-state lighting.

### BACKGROUND OF THE INVENTION

Solid-state lighting (SSL) is poised to become the dominant technology for general illumination, with enormous worldwide ramifications for human productivity and energy consumption. See J. Y. Tsao et al., J. Phys. D 43, 354001 (2010). As a consequence, huge efforts worldwide are aimed at continuing to increase its efficiency and decrease its cost.

Based on light-emitting diodes (LEDs), solid-state lighting has made remarkable progress such that it is now the most efficient source of light. At this point in time, SSL based on blue-emitting InGaN LEDs and phosphors has demonstrated the highest luminous efficacy (lm/W, lumens per optical watt) of any white light source: 265 lm/W (about triple the 70-90 lm/W of fluorescent lamps). See Y. Narukawa et al., J. Phys. D 43, 354002 (2010). However, several factors limit the performance of this LED. A versatile, high-performance solid-state light source must deliver high wall-plug efficiency over a large range of operating currents. In particular, the high luminous efficacy of LED-based SSL can only be achieved at relatively low (2.5 A/cm²) current densities. At higher current densities, InGaN LEDs experience a drop in efficiency (droop), limiting advances in efficiency with higher power devices. See M. R. Krames et al., J. Disp. Tech. 3, No. 2, (2007); and M. H. Crawford, IEEE J. Select. Topics Quantum Electron. 15, 1028 (2009). The droop arises from carrier loss mechanisms with stronger carrier density dependences than the radiative processes, e.g., Auger scattering. See Y. C. Shen et al., Appl. Phys. Lett. 91, 141101 (2007); and J. Iveland et al., Phys. Rev. Lett. 110, 177406 (2013). Also the luminous efficacy is limited due to the Stokes loss of converting blue photons to longer wavelengths to produce white light. Combining direct LED sources such as a red/green/blue to produce a white source increases the luminous efficacy, but the droop is still present in the InGaN emitters.

Proposals have been made to mitigate the droop problem and achieve high luminous efficacy at high current densities by replacing LEDs with lasers. See J. J. Wierer et al., Laser Photonics Rev. 7, 963 (2013), which is incorporated herein by reference. The reasoning is that carrier-population clamping after the onset of lasing limits carrier loss to that at threshold, while stimulated emission continues to grow with injection current. Semiconductor lasers, in particular, operate under stimulated emission mode beyond a threshold current. In the stimulated emission mode, every new carrier added to the light active region of the device produces light via stimulated emission. All the other recombination processes are clamped; meaning additional carriers arriving at the light emitting layers are not lost to non-radiative processes but go directly to stimulated emission. In particular, droop caused by Auger recombination, which is a problem for LEDs at high current densities, is not a problem in lasers beyond threshold.

Lasers, however, suffer from some potential drawbacks, including speckle, safety, and narrow linewidths. In particular, an RGB (red-green-blue) or RYGB (red-yellow-green-blue) white light source composed of three or four discrete laser lines far from fills the visible spectrum. However, it has recently been found that a laser-based white light illuminant comprising three or more semiconductor lasers, each having a discrete color, can be combined to provide a high color rendering index in a typical environment. See A. Neumann et al., Optics Express 19, A982 (2011); and U.S. application Ser. No. 13/433,518, filed Mar. 29, 2012, both of which is incorporated herein by reference. For example, a three-color laser-based white light illuminant comprising a red laser, a green laser, and a blue laser, preferably with wavelengths of approximately 609 nm, 541 nm, and 462 nm, can provide a color temperature of about 3000K. A four-color laser-based white light illuminant comprising a red laser, a yellow laser, a green laser, and a blue laser, preferably with wavelengths of approximately 614 nm, 573 nm, 530 nm, and 463 nm, can provide a color temperature of about 3000K and a color rendering index of about 90. The color temperature of the white light can be changed within the range of 2700 to 6500K by changing the relative power levels of the three or more semiconductor lasers. The luminous efficacy of the white light can be greater than 400 lm/W. The semiconductor lasers can comprise indium gallium nitride semiconductor lasers and/or aluminum indium gallium phosphide semiconductor lasers. A diffusion plate can be used to diffuse and mix the discrete beam colors to provide white light within one MacAdam ellipse. A diffractive optical element, a diffuser plate, and/or a piezoelectric element, can be used to reduce speckle of the white light. Alternatively, speckle can be reduced by using semiconductor lasers with a spectral linewidth of greater than 5 nm or by using more than one laser having the same color but with different coherence.

However, the extent to which efficiency droop can be solved by semiconductor lasers depends on a complicated interplay involving nonradiative losses, stimulated emission, spontaneous emission, and intracavity absorption. In particular, such lasers typically display poor performance below threshold. Therefore, a need remains for a solid-state light source that is suitable for general lighting applications, including as dimmable lights that enable energy savings.

### SUMMARY OF THE INVENTION

The present invention is directed to a solid-state light source comprising an array of nanolasers. The solid-state light source comprises at least one red nanolaser, at least one green nanolaser, and at least one blue nanolaser to provide an RGB white light source. For example, the wavelengths of the red, green, and blue nanolasers can be approximately 609 nm, 541 nm, and 462 nm. The light source can further comprise at least one yellow nanolaser to provide a RYGB white light source. For example, the wavelengths of the red, yellow, green, and blue nanolasers are approximately 614 nm, 573 nm, 530 nm, and 463 nm. The nanolasers comprise III-V semiconductor nanolasers, such as the III-nitride semiconductors, InGaN or GaN.

Nanolasers have certain advantages over LEDs and conventional semiconductor laser diodes for lighting applications. In particular, nano-cavities can channel spontaneous emission entirely into the lasing mode, so that all the emissions (spontaneous and stimulated) contribute to usable light output over a large range of current, enabling easily dimmable lighting.

### BRIEF DESCRIPTION OF THE DRAWINGS

The detailed description will refer to the following drawings, wherein like elements are referred to by like numbers.

FIGS. 1(a)-(c) are schematic illustrations of a light-emitting diode, a vertical-cavity surface emitting laser, and a nanolaser, respectively, that can be used for solid-state lighting.

FIG. 2(a) is a graph of output power and FIG. 2(b) is a graph of efficiency versus injection current for an LED (dotted curve) and an array of 9 VCSELs. The solid curves show the cases where lasing threshold is reachable because of sufficiently low cavity loss (γ_{abs}=1 and 2 ps⁻¹). The dashed curve is for (γ_{abs}=4 ps⁻¹, where lasing is not possible. For reference to following figures the spontaneous emission factor is β=0.01.

FIG. 3(a) is a graph of output power and FIG. 3(b) is a graph of efficiency versus injection current for an LED (dotted curve) and an array of 144 nanolasers with spontaneous emission factor β=1. The solid curves show the cases where lasing threshold is reachable because of sufficiently low cavity loss (γ_{abs}=1 and 2 ps⁻¹). The dashed curve is for γ_{abs}=4 ps⁻¹, where lasing is not possible.

FIG. 4 is a graph comparing internal quantum efficiency (IQE) versus current for an LED, conventional laser, and a nanolaser array.

FIG. 5 is a graph of equal-time intensity autocorrelation versus injection current for nanolaser with spontaneous emission factor β=1. With absorption γ_{abs}=1 and 2 ps⁻¹ (solid and dashed curves, respectively), there is clear transition from thermal (g⁽²⁾(0)=2) to coherent (g⁽²⁾(0)=1) photon statistics. The dotted curve shows the nonlasing case with γ_{abs}=4 ps⁻¹.

### DETAILED DESCRIPTION OF THE INVENTION

As described above, it has been proposed that the efficiency droop in solid-state light emitters can be mitigated by replacing InGaN light-emitting diodes (LEDs) with lasers. The argument in favor of this approach is that carrier-population clamping after the onset of lasing limits carrier loss to that at threshold, while stimulated emission continues to grow with injection current. As described below, a fully quantized (carriers and light) theory that is applicable to LEDs and lasers (above and below threshold) confirms the potential advantage of higher laser output power and efficiency above lasing threshold, while also indicating disadvantages including low efficiency prior to lasing onset, sensitivity of lasing threshold to temperature, and the effects of catastrophic laser failure. Therefore, the present invention is directed to nanolaser arrays as a solution to some of these concerns for lighting applications.

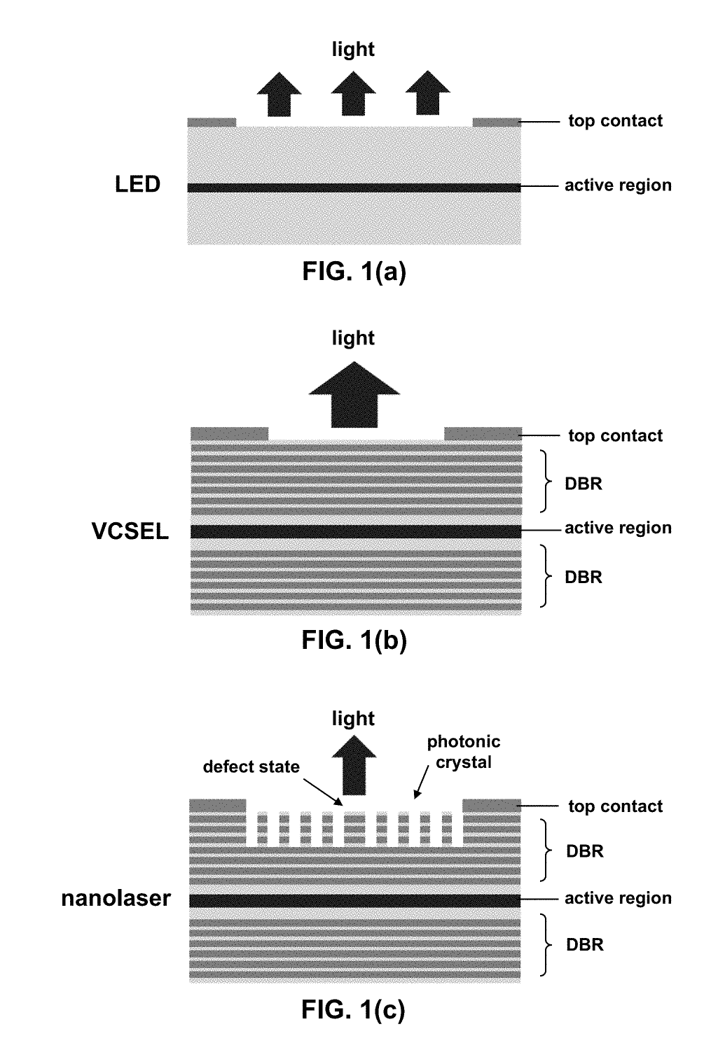

A fully quantized (carriers and light) theory was used to evaluate the utility of replacing InGaN LEDs with lasers. It gives a consistent description of spontaneous and stimulation emission, and therefore, is applicable to LEDs, as well as lasers above and below lasing threshold. FIGS. 1(a)-(c) depict the devices compared herein for solid-state lighting applications: an LED without an optical cavity, a vertical-cavity surface emitting laser (VCSEL) with an optical cavity defined by distributive Bragg reflectors (DBRs), and a nanolaser with a smaller optical cavity providing further control of spontaneous emission. The example of a nanolaser emitting from a defect site in a photonic lattice is used. See O. Painter et al., Science 284, 1819 (1999) and T. Watanable et al., Appl. Phys. Lett 104, 121108 (2014), which are incorporated by reference. Results from the cavity-QED modeling apply equally well to metallic-cavity lasers. See M. T. Hill et al., Nat. Photonics 1, 589 (2007), which is incorporated by reference. Other types of nanolasers can also be used with the present invention. A comparison of performance between an LED, a VCSEL array, and a nanolaser array, all with the same active region configuration, is described below.

To develop a device model applicable to all three device configurations, the starting point is the Hamiltonian

$$H = {\sum }_{l} {ℏω}_{l} ( {a}_{l}^{} {a}_{l} + \frac{1}{2} ) + {\sum }_{k ⊥} {ɛ}_{k ⊥}^{e} {c}_{k ⊥}^{} {c}_{k ⊥} + {\sum }_{k ⊥} {ɛ}_{k ⊥}^{h} {b}_{k ⊥}^{} {b}_{k ⊥} - ℏ {\sum }_{k ⊥ , l} ( {g}_{k ⊥ l} {b}_{k ⊥}^{} {c}_{k ⊥}^{} {a}_{l} + {g}_{k ⊥ l}^{*} {a}_{l}^{} {c}_{k ⊥} {b}_{k ⊥} ) , \qquad ( 1 )$$

where [symbol] ωₗ is the photon energy in cavity mode l, aₗ [symbol] and aₗ are its photon creation and annihilation operators, ε_{k⊥}^{e} and ε_{k⊥}^{h} are the quantum-well (QW) electron and hole energies, c_{k⊥} [symbol] and c_{k⊥} are creation and annihilation operators for electrons, b_{k⊥} [symbol] and b_{k⊥} are the corresponding operators for holes, and the summations are over the photon modes and two-dimension momentum (k_{⊥}) states of the quantum wells. See E. Jaynes and F. W. Cummings, Proc. IEEE 51, 89 (1963). The light-matter coupling coefficient is

$${g}_{k ⊥ l} = \sqrt{\frac{{ω}_{l}}{{ℏɛ}_{b} V}} {W}_{l} ( {Z}_{QW} ) \frac{1}{{V}_{a}} {\int }_{{V}_{a}} {d}^{3} {RC}_{k ⊥} ( R ) {V}_{k ⊥} ( R ) , \qquad ( 2 )$$

where [symbol] is the bulk material dipole matrix element, ε_{b} is the background permittivity, V is the optical mode volume, Wₗ(Z_{QW}) is the amplitude of the lth passive optical mode eigenfunction at Z_{QW}, the location of the quantum-well active region, and the integral is over the active region volume Vₐ, of electron and hole envelop functions, C_{k⊥}(R) and V_{k⊥}(R), respectively.

Using the above Hamiltonian and working in the Heisenberg Picture, the equations of motion can be derived for the polarization p_{k⊥/}= [symbol] c_{k⊥} [symbol] b_{k⊥} [symbol] aₗ [symbol] , photon population [symbol] nₗ^{p}=aₗ [symbol] aₗ [symbol] and carrier populations n_{k⊥}^{e}= [symbol] c_{k⊥} [symbol] c_{k⊥} [symbol] and n_{k⊥}^{h}= [symbol] b_{k⊥} [symbol] b_{k⊥} [symbol] . The following closed set of equations is obtained by assuming a random phase approximation, keeping only correlations at the doublet level:

$$\begin{matrix}\frac{{dp}_{k ⊥ l}}{dt} = - [ i ( {ω}_{l} - {ω}_{k ⊥} ) + ( γ + {γ}_{c} ) ] {p}_{k ⊥ l} + {g}_{k ⊥ l}^{*} [ {n}_{k ⊥}^{e} {n}_{k ⊥}^{h} + ( {n}_{k ⊥}^{e} + {n}_{k ⊥}^{h} - 1 ) {n}_{l}^{p} ] , & ( 3 ) \\ \frac{{dn}_{l}^{p}}{dt} = 2 {\sum }_{k ⊥} {g}_{k ⊥ l} Re ( {p}_{k ⊥ l} ) - 2 {γ}_{c} {n}_{l}^{p} , & ( 4 ) \\ \frac{{dn}_{k ⊥}^{σ}}{dt} = - 2 {\sum }_{k ⊥} {g}_{k ⊥ l} Re ( {p}_{k ⊥ l} ) - {γ}_{nl} {n}_{k ⊥}^{e} {n}_{k ⊥}^{h} - {γ}_{nr} {n}_{k ⊥}^{σ} - {γ}_{c - c} [ {n}_{k ⊥}^{σ} - f ( {ɛ}_{k ⊥}^{σ} , {μ}_{σ} , T ) ] - {γ}_{c - p} [ {n}_{k ⊥}^{σ} - f ( {ɛ}_{k ⊥}^{σ} , {μ}_{σ}^{l} , {T}_{l} ) ] , & ( 5 )\end{matrix}$$

where ω_{k⊥} is the transition frequency, γ is the dephasing rate, γₙₗ is the spontaneous emission rate into nonlasing modes, and σ=e (h) labels the electron (hole). See M. Kira and S. W. Koch, Semiconductor Quantum Optics (Cambridge University Press, Cambridge, 2012). The photon decay rate in the cavity is 2γ_{c}=γ_{abs}+γₒᵤₜ, where γ_{abs} is the absorption loss rate and γₒᵤₜ is the outcoupling loss rate. In this momentum-resolved treatment, the nonradiative carrier loss rate is described as γₙᵣ=A+CN², where N is the average of electron and hole densities. See W. W. Chow et al., Appl. Phys. Lett. 97, 121105 (2010). The coefficient A is often associated with defect-related loss and C is the coefficient representing carrier-loss processes leading to the efficiency droop, such as the Auger coefficient. See Y. C. Shen et al., Appl. Phys. Lett. 91, 141101 (2007). The quantum-well states are populated via the barriers, where an injection current l creates the carrier population nₖ^{σ}

$$\frac{{dn}_{k}^{σ}}{dt} = \frac{l}{{eN}_{σ}^{p}} f ( {ɛ}_{k}^{σ} , {μ}_{σ}^{p} , {T}_{p} ) ( 1 - {n}_{k}^{σ} ) - {γ}_{nr} {n}_{k}^{σ} - {γ}_{c - c} [ {n}_{k}^{σ} - f ( {ɛ}_{k}^{σ} , {μ}_{σ} , T ) ] - {γ}_{c - p} [ {n}_{k}^{σ} - f ( {ɛ}_{k}^{σ} , {μ}_{σ}^{l} , {T}_{l} ) ] . \qquad ( 6 )$$

In Eq. (6), k is the 3-dimensional carrier momentum associated with the barrier (bulk) states, e is the electron charge, and N_{σ}^{p}=Σₖf(εₖ^{σ},μ_{σ}^{p},Tₚ) is the steady-state bulk carrier population created by the injection current when all radiative processes are switched off. The injected carrier distribution f(εₖ^{σ},μ_{σ}^{p},Tₚ) is a Fermi-Dirac function with chemical potential μ_{σ}^{p} and temperature Tₚ.

In the above equations of motion, scattering effects lead to polarization dephasing, carrier capture, and escape into and out of quantum-well and bulk states. They are treated phenomenologically via the terms containing γ (dephasing rate), γ_{c-c} (carrier-carrier scattering rate), and γ_{c-p} (carrier-phonon scattering rate). The carrier capture and relaxation processes are modeled as follows. Carrier-carrier collisions are fast and they tend to drive a carrier population to quasi-equilibrium described by a Fermi-Dirac function at chemical potential and plasma temperature, μ_{σ} and T, respectively. Carrier-phonon collisions are slower and they further relax the carrier distribution to another Fermi-Dirac function given by chemical potential μ_{σ}^{l} and lattice temperature Tₗ. For the asymptotic Fermi-Dirac distributions approached via carrier-carrier collisions f(εₖ^{σ},μ_{σ},T), the chemical potential μ_{σ} and plasma temperature Tare determined by conservation of carrier population and energy. For (εₖ^{σ},μ_{σ}^{l},Tₗ), which are reached via carrier-phonon collisions, the chemical potential μ_{σ}^{l} is determined by conservation of carrier population and the lattice temperature Tₗ is an input quantity. Details and comparison with quantum kinetic treatments may be found elsewhere. See W. W. Chow et al., IEEE J. Quantum Electron. 38, 402 (2002); and I. Waldmueller et al., IEEE J. Quantum Electron. 42, 292 (2006).

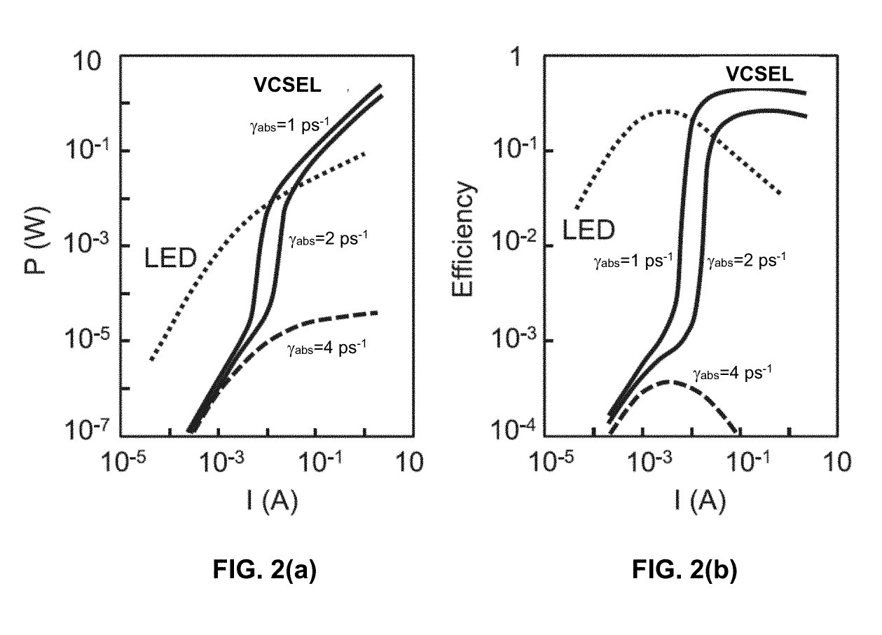

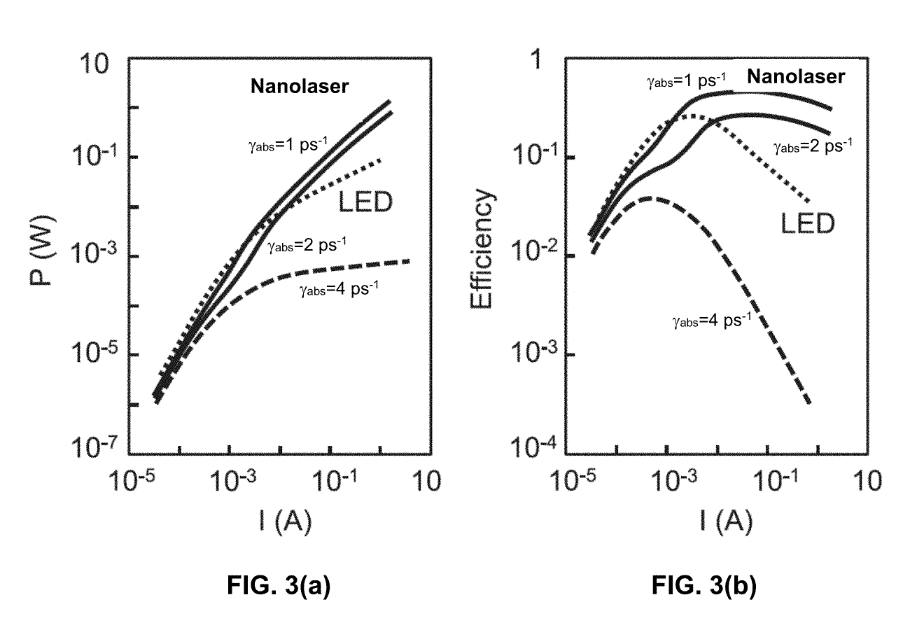

As an example, results are presented from simulations assuming an active medium consisting of a 2 nm In_{0.37}Ga_{0.63}N quantum well between GaN barriers. Detailed experimental and theoretical studies were recently reported on the excitation and temperature dependences of efficiency in an LED with this quantum-well structure. See K. Fujiwara et al., Phys. Status Solidi C 6, S814 (2009); J. Hader et al., Appl. Phys. Lett. 99, 181127 (2011); and W. W. Chow, Opt. Express 22, 1413 (2014). The narrow, single quantum-well active region avoided complications from non-uniform carrier populations and screening of the quantum-confined Stark effect. Other quantum-well structures were modeled, with quantum-well indium concentration ranging from 0.2 to 0.4, width from 2 nm to 3.5 nm, and number from 1 to 5 layers. In Eqs. (3)-(5), the changes occur in the band dispersion γ_{k⊥}^{σ}, light-matter coupling coefficient g_{k⊥/}, and the number of subbands. The shape changes and relative placements of the output power and efficiency versus injection current curves, as shown in FIGS. 2(a)-(b) and FIGS. 3(a)-(b), due to effects of the optical cavity are essentially insensitive to details of the gain structure.

The band structure calculation for the 2 nm In_{0.37}Ga_{0.63}N/GaN quantum well gives the electron and hole effective masses 0.185 m₀ and 0.652 m₀, respectively, and light-matter coupling coefficient (averaged over the spontaneous emission linewidth) g̅_̅{̅k̅⊥̅/̅}̅=2.68×10¹¹ s⁻¹, where m₀ is the bare electron mass and the parabolic-band approximation is used. The other input parameters to the calculation are the carrier population loss rates, and capture and relaxation rates, which are given in terms of effective carrier-carrier and carrier phonon relaxation coefficients. They are obtained from fit to experiment: γ=γ_{c-c}=5×10¹³ s⁻¹; γₙᵣ=10⁶ s⁻¹; γ_{c-p}=10¹² s⁻¹, and C=3×10⁻³¹ cm⁶ s⁻¹. See W. W. Chow, Opt. Express 22, 1413 (2014). A value of C is chosen to give the onset of droop at around 10 A/cm², as measured in most experiments. The value is also consistent with that reported from a first-principles calculation for phonon assisted Auger scattering. See E. Kioupakis et al., Appl. Phys. Left. 98, 161107 (2011).

The dotted curves in FIGS. 2(a)-(b) and FIGS. 2(a)-(b) show the computed steady state output power P=γₒᵤₜ [symbol] ωₗnₗ^{p} and efficiency η=eP/(^{l}μ_{ef}) versus injection current for an LED with active area 100 μm×100 μm and at lattice temperature 300 K. In practice, the solid-state lighting LED is a highly complex device, with much effort directed towards maximizing out-coupling of light and carrier injection efficiency. These simulations assumed the limiting case, where these efforts produce unity carrier injection efficiency, with the exception of Fermi blocking at high excitation, as well as 100% light-extraction efficiency, leading to, e.g., no absorption. In the expression for η, μ_{ef} is the electron-hole chemical potential separation, which is determined during the solution for the quasi-equilibrium carrier distributions. Past an injection current of l=1 mA, the dotted curves indicate a saturation in output power and a corresponding decrease in efficiency (FIGS. 2(a) and 2(b), respectively).

Next, the laser approach is demonstrated using a 3×3 array of VCSELs, where each VCSEL has a 5.6 μm×5.6 μm emitting cross section. The array size is chosen to produce an output of P=1 W at l=1 A current. If spaced over a 100 μm×100 μm area, similar to that of the LED aperture, the VCSEL array has a 3% fill factor. The calculation assumes DBR reflectivities giving γₒᵤₜ=1 ps⁻¹ and emission into nonlasing modes γₙₗ=5×10⁸ s⁻¹, where the latter gives a spontaneous emission factor of β=0.01 via

$$β = \frac{2 {\sum }_{k ⊥ l} {g}_{k ⊥ l} {Re ( {p}_{k ⊥ l}^{′} )}_{ss}}{2 {\sum }_{k ⊥ l} {g}_{k ⊥ l} {Re ( {p}_{k ⊥ l}^{′} )}_{ss} + {γ}_{nl} {\sum }_{k ⊥ l} {n}_{k ⊥}^{e} {n}_{k ⊥}^{h}} . \qquad ( 7 )$$

See G. Bjork and Y. Yamamoto, IEEE J. Quantum Electron. 27, 2386 (1991). The polarization p_{k⊥/}′ is obtained by solving

$$\frac{{dp}_{k ⊥ l}^{′}}{dt} = {g}_{k ⊥ l} {n}_{k ⊥}^{e} {n}_{k ⊥}^{h} \qquad ( 8 )$$

together with Eqs. (3)-(6) and the subscript ss indicates the steady-state solution.

In FIGS. 2(a)-(b), the solid curves are plots of output power and efficiency versus injection current, for absorption γ_{abs}=1 ps⁻¹ and 2 ps⁻¹, which are within the range of absorption coefficient (10 cm⁻¹≦σ_{abs}≦81 cm⁻¹) measured for InGaN quantum-well structures. See S.-S. Schad et al., J. Lightwave Technol. 22, 2323 (2004). In the log-log plot of FIG. 2(a), they have the typical “S” shape, where the jump in output power locates the lasing threshold. See G. Bjork and Y. Yamamoto, IEEE J. Quantum Electron. 27, 2386 (1991). The results support the argument favoring lasers for solid-state lighting in that after lasing threshold is reached, the emission from the laser continues to increase with injection current and far outpaces that of the LED. FIG. 2(b) depicts a corresponding recovery of efficiency, to that of the LED prior to the onset of droop.

While a broad parameter space, involving array size, quantum-well structure, and optical-cavity configuration, is available for device optimization, the plots in FIGS. 2(a)-(b) show some general issues that can affect the use of lasers in solid-state lighting. One is the significant suppression of emission before lasing. It may not be a concern with high-intensity lighting applications, where laser operation will be far above lasing threshold. However, it can limit the use of lasers in general lighting applications, e.g., where dimmable lights are advantageous for energy savings. Another concern is output power control because of sensitivity of lasing threshold to temperature or absorption variations. The vertical separation between the two solid curves illustrates the output power difference on a log scale when threshold current changes due to changes in γ_{abs}. Finally, laser failure can occur from degradation of the active region or increase in optical losses, e.g., from facet damage. The dashed curves in FIGS. 2(a)-(b) illustrates the change in device performance when absorption is increased to give γ_{abs}=4 ps⁻¹, resulting in lasing being unreachable.

It may be argued that most of the above concerns will vanish with lowering of laser threshold. There is, however, a basic physical obstacle. Numerical simulations show the onset of droop to occur at very low carrier occupations. At the zone center (k_{⊥}=0), where the carrier occupation is highest, typically n_{k⊥}^{e},n_{k⊥}^{h}<0.2 at the efficiency peak. This is far below the occupation necessary for gain: n_{k⊥}^{e}+n_{k⊥}^{h}>1. In other words, the onset of gain will always be at injection currents appreciable higher than where droop appears.

A solution may come from a special class of nanolasers, with γₙₗ=0 or spontaneous emission factor β=1. A nanolaser is a tiny laser that uses nanowires or similar nano-optical devices to produce very fine beams of coherent light, rather than the traditional optical pumping process of a conventional laser. While the technology is still relatively new, there are experiments involving photonic lattices or plasmonic cavities demonstrating efficient channeling of spontaneous emission into the lasing mode. See O. Painter et al., Science 284, 1819 (1999); M. T. Hill et al., Nat. Photonics 1, 589 (2007); and M. Khajavikhan et al., Nature 482, 204 (2012), which are incorporated herein by reference. The possibility of extremely high-quality (Q-factor) nanocavities also allows for lasing with very few emitters in the active region. Therefore, nanolasers can comprise a few emitters or even a single emitter with low intracavity photon numbers sustained by stimulated emission. In particular, novel nano-optical structures, such as pillar vertical-cavity surface emitting lasers, microdisks, photonic lattices, nanowires, and plasmonic resonators enable the extension of optical mode confinement from one to three dimensions. See S. Reitzenstein et al., Appl. Phys. Lett. 89, 051107 (2006); S. Strauf et al., Phys. Rev. Lett. 96, 127404 (2006); S. M. Ulrich et al., Phys. Rev. Lett. 98, 043906 (2007); Z. G. Xie et al., Phys. Rev. Lett. 98, 117401 (2007); S. Reitzenstein et al., Opt. Express 16, 4848 (2008); M. Nomura et al., Nat. Phys. 6, 279 (2010); J. Wiersig et al., Nature 460, 245 (2009); M. T. Hill et al., Nature Photon. 1, 589 (2007); C.-Y. Lu et al., Opt. Lett. 36, 2447 (2011); C.-Y. Lu and S. L. Chuang, Opt. Exp. 19, 13225 (2011); Si-Young Bae et al., Optics Express 21(14), 16854 (2013); H. Liu et al., Nanotechnology 27, 355201 (2016); Q. Li et al., Optics Express 20(16), 17873 (2012); and S. Arafin et al., J. Nanophotonics 7, 074599-1 (2013), which are incorporated herein by reference. 3D mode confinement provides spectrally widely separated cavity modes allowing for the possibility of only one mode overlapping with the spontaneous emission spectrum—i.e., all emission is channeled into a single laser mode. See P. L. Gourley, Nature 371, 571 (1994); K. J. Vahala, Nature 424, 839 (2003); P. Lodahl et al., Nature 430, 654 (2004); and D. J. Bergman and M. I. Stockman, Phys. Rev. Left. 90, 027402 (2003).

A key feature of the nanolaser is the efficient channeling of spontaneous emission in the lasing mode. The spontaneous emission factor β is a quantitative measure of optical resonator control over spontaneous emission. This factor is defined as the spontaneous emission rate into the laser mode divided by the total spontaneous emission rate. For small values of β, which are typical for conventional lasers, the onset of stimulated emission produces a distinct jump in output intensity. Recent advances in micro- and nano-cavities with 3D optical mode confinement have led to β-factors approaching unity for nanolasers. When there is a high degree of spontaneous emission (the spontaneous emission factor β is set to 1), the output power increases almost constantly with increasing current. In these cases, the intensity jump seen with conventional lasers vanishes, which leads to the possibility of ultralow-threshold or even thresholdless lasers. See S. Reitzenstein et al., Appl. Phys. Left. 89, 051107 (2006); S. Strauf et al., Phys. Rev. Lett. 96, 127404 (2006); S. M. Ulrich et al., Phys. Rev. Lett. 98, 043906 (2007); H. Yokoyama and S. D. Brorson, J. Appl. Phys. 66, 4801 (1989); M. Khajavikhan et al., Nature 482, 204 (2012); H. Yokoyama, Science 256, 66 (1992); and F. De Martini and G. R. Jacobovitz, Phys. Rev. Lett. 60, 1711 (1988).

FIGS. 3(a)-(b) show the results from modeling a 12×12 array of nanolasers, each with cross-section of 560 nm×560 nm, giving a 0.5% fill factor compared to the VCSEL array. Again, the array size is chosen to give 1 W output power at 1 A injected current. Comparison with FIGS. 2(a)-(b) shows that the increase from β=0.01 to β=1 results in efficiency below lasing threshold increasing by about two orders of magnitude, to just slightly below that of the LED at the same current (FIG. 3(b)). FIG. 3(a) depicts a vanishing of the “S” shape, so that the output power increases almost constantly with increasing current, in sharp contrast to the LED which exhibits strong saturation, and to the conventional laser which exhibits significant output suppression at low current. Sensitivity of output to threshold current variation is also reduced, as evident from the closeness of the two solid curves. While less serious than the case of the VCSEL array (compare dashed curves in FIGS. 2(a)-(b) and FIGS. 3(a)-(b)), the failure to lase still noticeably degrades device performance, because of high absorption in the InGaN/GaN material system. See S.-S. Schad et al., J. Lightwave Technol. 22, 2323 (2004).

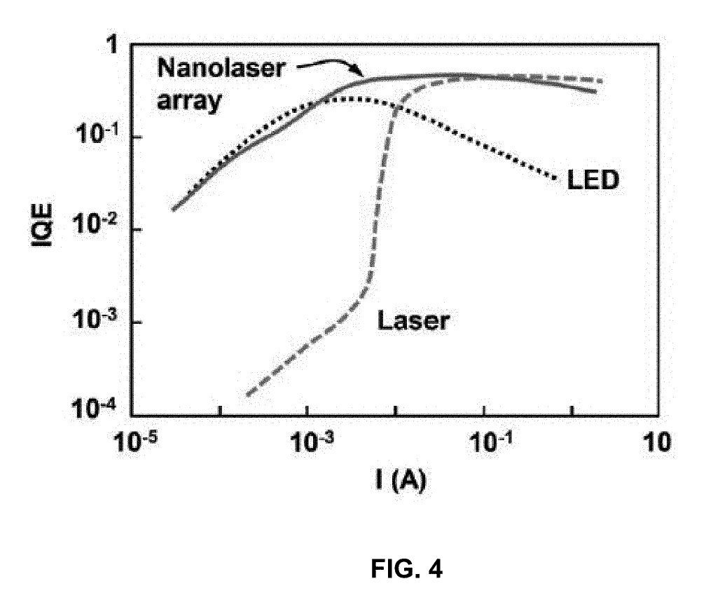

FIG. 4 compares the internal quantum efficiency (IQE) of the LED, conventional laser, and nanolaser array. The nanolaser enables high IQE over a large range of drive currents. Therefore, nanolasers may enable dimmable lighting by simply turning down the drive current, rather than having to turn off some fraction of the LEDs in an array to dim the lighting. Further, using nanolasers allows lower power than convention lasers with simpler electronics, since there is no requirement for addressable current injection.

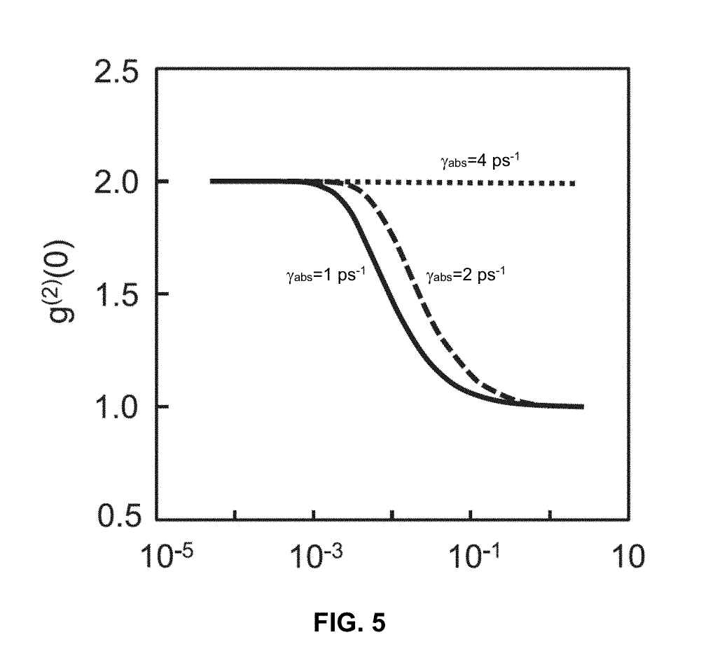

The improvements with nanolasers are achieved without invoking risky or much-debated concepts, such as thresholdless lasing. See M. Khajavikhan et al., Nature 482, 204 (2012). FIG. 5 shows the plots of the equal-time intensity autocorrelation from one of the nanolasers, using

$${g}^{( 2 )} ( 0 ) = \frac{{〈 {a}_{l}^{} {a}_{l}^{} {a}_{l} a 〉}_{lss}}{{( {n}_{l}^{p} )}_{ss}^{2}} , \qquad ( 9 )$$

where the evaluation involved numerical solution of equations of motion for correlations up to the quadruplet level. See W. W. Chow et al., Light Sci. Appl. 3, 201 (2014). The solid and dashed curves indicate that a clear transition remains between thermal (g⁽²⁾(0)=2) and coherent (g⁽²⁾(0)=1) photon statistics. The existence of a lasing threshold (based on g⁽²⁾(0) and the Fano-Mandel parameter) for β=1 lasers has been reported for microcavity semiconductor lasers. See R. Jin et al., Phys. Rev. A 49, 4308 (1994). For the nonlasing situation (dotted curve), g⁽²⁾(0) remains essentially at 2. The feature of β=1 that is used to advantage is the disappearance of the “S” shape in the log-log input-output dependence. The fact that the output may be incoherent or partially coherent is acceptable for most lighting applications.

Finally, with β=1, the beam divergence remains the same below and above lasing thresholds. While this is very desirable for some applications, even greater functionality can be achieved if this ideal requirement is relaxed and instead all spontaneous emission is channeled into multiple forward-directed modes. The ability to transition from a wider, low-intensity beam below threshold to a single-mode collimated, high-intensity beam above threshold may enable smart lighting concepts, e.g., headlights with tailorable properties. Fabrication challenges will also be relaxed or one may use a laser with a larger optical cavity.

To achieve a white light source, three or more nanolasers or nanolaser arrays, each having a discrete color, can be combined to provide a high color rendering index. For example, an RGB nanolaser-based white light source can comprise a red nanolaser, a green nanolaser, and a blue nanolaser, preferably with wavelengths of approximately 609 nm, 541 nm, and 462 nm. A RYGB nanolaser-based white light source can comprise a red nanolaser, a yellow nanolaser, a green nanolaser, and a blue nanolaser, preferably with wavelengths of approximately 614 nm, 573 nm, 530 nm, and 463 nm. For example, the nanolasers can comprise indium gallium nitride semiconductor nanolasers and/or aluminum indium gallium phosphide semiconductor nanolasers.

The present invention has been described as nanolasers for solid-state lighting. It will be understood that the above description is merely illustrative of the applications of the principles of the present invention, the scope of which is to be determined by the claims viewed in light of the specification. Other variants and modifications of the invention will be apparent to those of skill in the art.

I claim:

1. A solid-state light source comprising at least one red nanolaser, at least one green nanolaser, and at least one blue nanolaser.

2. The solid-state light source of claim 1, wherein the nanolasers comprise III-V semiconductors.

3. The solid-state light source of claim 2, wherein the III-V semiconductors comprises a III-nitride semiconductor.

4. The solid-state light source of claim 3, wherein the III-nitride semiconductor comprises InGaN or GaN.

5. The solid-state light source of claim 1, wherein the wavelengths of the red, green, and blue nanolasers are approximately 609 nm, 541 nm, and 462 nm.

6. The solid-state light source of claim 1, further comprising at least one yellow nanolaser.

7. The solid-state light source of claim 6, wherein the wavelengths of the red, yellow, green, and blue nanolasers are approximately 614 nm, 573 nm, 530 nm, and 463 nm.

8. The solid-state light source of claim 1, further comprising one or more phosphors that convert at least a portion of the nanolaser light to longer wavelength light, wherein the spectral power density of the unconverted laser light and the phosphor-converted light produces white light.

9. The solid-state light source of claim 1, wherein the at least one red, green, or blue nanolaser comprises a pillar vertical-cavity surface emitting laser, microdisk laser, photonic lattice laser, nanowire laser, or plasmonic resonator laser.
